(19) United States
(12) Patent Application Publication
(10) Pub. No.: US 2007/0257685 A1
(43) Pub. Date: Nov. 8, 2007

(54) Probe and probe card

(75) Inventor: Jun Mochizuki, Tokyo (JP)

Correspondence Address: MASUVALLEY & PARTNERS, 8765 AERO DRIVE, SUITE 312, SAN DIEGO, CA, 92123, US

(73) Assignee: Tokyo Electron LTD., Tokyo (JP)

(21) Appl. No.: 11/646,143

(22) Filed: Dec. 27, 2006

(30) Foreign Application Priority Data
May 8, 2006 (JP) 2006-129112

(51) Int. Cl. G01R 31/02

(52) U.S. Cl. 324/754

(57) ABSTRACT

The objective of present invention is to obtain high positioning accuracy while securing moving space for a probe positioned by insertion into a through-hole. For this reason, a probe having a perpendicular portion where a lower face contacts an electrode, and a beam formed in a horizontal direction from a top edge of the perpendicular portion. A locking portion protrudes outward and is formed on the perpendicular portion. A taper portion, having a diameter gradually increasing from a lower side of the locking portion is formed on the perpendicular portion. This taper portion is formed on the face on the opposite of the direction in which the beam portion is formed on the perpendicular portion. When the perpendicular portion of the probe is inserted into a through-hole, the perpendicular portion is guided by the taper portion, and locked to the upper end of the through-hole by the locking portion.

### TECHNICAL FIELD

The present invention relates to a probe and a probe card for examining electrical characteristics of an examination object, such as a wafer.

### BACKGROUND OF INVENTION

For example, examinations of electrical characteristics of an electronic circuit such as an IC or an LSI formed on a semiconductor wafer have been typically carried out by bringing a plurality of probes attached to a probe card of an examination device into a contact with electrodes of an electrical circuit on a wafer, and sending electrical signals for examination from the probes to the electrical circuit.

Also, when conducting the above electrical characteristics examination, for example, in Japanese published unexamined patent application no. 2004-85261, an oxide film on the surface of the electrode is scraped away (hereinafter referred as “scrub”) by horizontally moving probes on the electrode surface on a wafer using elasticity of the probes. This allows electrical continuity of the probes and the electrodes.

Meantime, in a probe card, in case a probe 200 is positioned by inserting the probe 200 into the through-hole 201a of supporting plate 201 as shown in FIG. 9, a clearance C between the through-hole 201a and the probe 200 needs to be decreased when trying to secure high positioning accuracy of the probe 200. In this case, there is a possibility for the above scrub not being done properly due to decrease of moving space of the probe 200 inside of the through-hole 201a.

In contrast, the probe 200 may be deviated randomly inside of the through hole 201a when increasing the clearance C between the through-hole 201a and the probe 200 in order to secure moving space of the probe 200. In this case, high positioning accuracy of the probe 200 can not be obtained and there is risk for possible unstable contact of the probe 200 and electrode.

In this way, an issue of securing moving space for the probe 200 and an issue of positioning accuracy are in a trade-off relationship, and it has been difficult to maintain high positioning accuracy of the probe 200 while securing moving space of the probe 200 in the probe card with the above configuration.

The present invention has been made in consideration of such a point, and for the probe positioned by inserting in a through-hole, it is therefore an object of the present invention to obtain high positioning accuracy of the probe while securing moving space of the probe for scrubbing.

### BRIEF SUMMARY OF THE INVENTION

A probe for examining electrical characteristics of an examination object by contacting an examination object, wherein the probe is positioned by insertion into a through-hole of another member, having an insertion portion to be inserted into the through-hole, and characterized by forming a taper portion on the insertion portion in a way that the diameter gradually increases from an insertion exit side of the through-hole to an insertion entry side.

According to the present invention, since the taper portion is formed on the insertion portion of the probe, the position of the probe is guided by the taper portion and stabilized even if a relatively large clearance is provided between the probe and the through-hole. As a result, high positioning accuracy of the probe can be obtained while securing moving space of the probe inside of the through-hole.

This probe has a perpendicular portion and its lower end contacts an examination object, and a beam portion that is connected to an upper end of the perpendicular portion and formed in a horizontal direction, the perpendicular portion is a insertion portion that is inserted into the through-hole, and a taper portion can be formed on the perpendicular portion.

Further, the taper portion described above can be formed on a face opposite from the direction that the beam portion was formed relative to the perpendicular portion.

And, on this perpendicular portion, a locking portion to be locked at an edge on insertion entry side of the through-hole can be formed.

The taper portion can be formed in a way that the apex where the taper diameter is maximum, is connected to the locking portion.

Further, a diameter of an apex of the taper portion can be configured equal to the diameter of the through-hole.

As another embodiment of the present invention, a probe for examining electrical characteristics of an examination object by contacting the examination object, where the probe is positioned by insertion into the through-hole of another member, and characterized by a taper portion which is formed to increase the positioning accuracy.

This probe has a perpendicular portion and its lower end contacts an examination object, and a beam portion that connects to the upper end of the perpendicular portion and is formed in a horizontal direction, the perpendicular portion is an insertion portion that is inserted into the through-hole, and a taper portion can be formed on the perpendicular portion.

Further, the taper portion described above can be formed on a face opposite from the direction that the beam portion is formed relative to the perpendicular portion.

And, onto this perpendicular portion, a locking portion to be locked at an edge on an insertion entry side of the through-hole can be formed.

The taper portion can be formed in a way that the apex where the taper diameter is maximum, is connected to the locking portion.

Further, a diameter of an apex of the taper portion can be configured equal to the diameter of the through-hole.

Also, another embodiment of the probe card, a probe for examining electrical characteristics of an examination object by contacting an examination object, wherein the probe is positioned by insertion into a through-hole of a probe supporting plate, having an insertion portion to be inserted into the through-hole, a taper portion having a diameter gradually increasing from an insertion exit side to an insertion entry side and a locking portion which is locked on the edge on the insertion exit side of the through-hole are formed on the insertion portion, grooves in a plurality of rows formed on the probe supporting plate, and characterized by locking a plurality of probes to the grooves through the locking portion such that the plurality of probes face each other.

And, in this probe card, each of the plurality of probes can be arranged in a way that the distance from a lower contacting portion which is the lower end of the probe insertion portion when viewed from a horizontal direction to the upper contacting portion which is provided on the upper end of the probe when viewed from the vertical is different from one another.

According to the present invention, since the positioning accuracy of the probe is increased, the probe can be robustly contacted to the electrodes and the probe can be examined stably. Also, since the probe scrubs the examination object properly, electrical continuity of the probe and the examination object can be made and the electrical characteristics can be examined with high accuracy.

### BRIEF DESCRIPTION OF THE DRAWINGS

FIG. 1 is an explanatory diagram showing a configuration of probe according to the embodiment.

FIG. 2 is an explanatory diagram showing a condition of a probe when a force is applied from a lower side.

FIG. 3 is a side view showing an outline of a configuration of a prober applied to a probe according to the embodiment.

FIG. 4 is a longitudinal section of a probe supporting plate with a probe locked.

FIG. 5 is an explanatory diagram showing a plurality of probes attached to a probe supporting plate.

FIG. 6 is a longitudinal section of a probe supporting plate locked to a probe having two beam portions on a lower contact.

FIG. 7 is an explanatory diagram showing a cantilever type probe.

FIG. 8 is an explanatory diagram showing a probe with taper portions formed on both sides.

FIG. 9 is an explanatory diagram showing a probe in prior art inserted into a through-hole of the probe supporting plate.

### DETAILED DESCRIPTION OF INVENTION

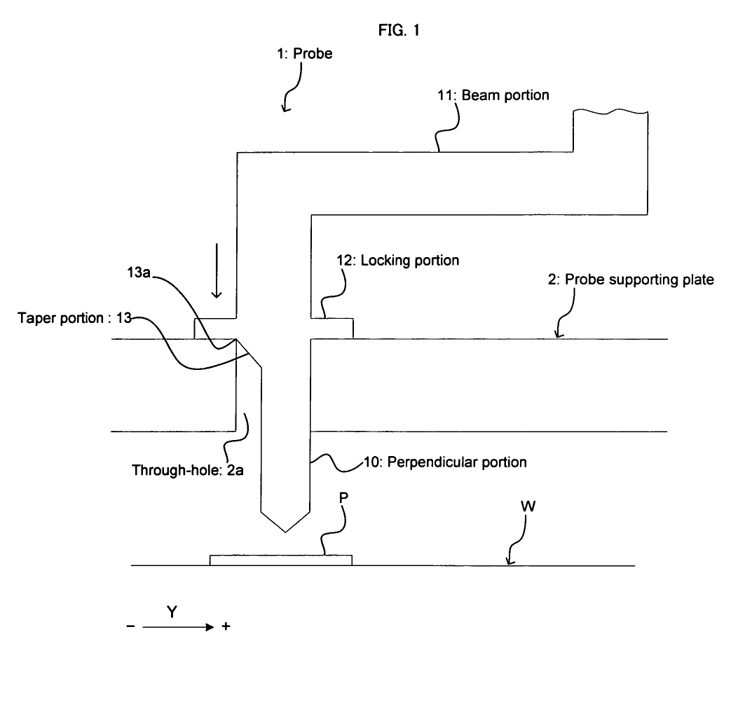

Preferable embodiments of the present invention will hereinafter be described. FIG. 1 is a longitudinal section showing a probe 1 and according to the embodiment is supported by a probe supporting plate 2 as another member having a through-hole 2a.

The probe 1, for example, having a perpendicular portion 10 and its lower end is brought into a contact with an electrode P of wafer W as an examination object, and a linear beam portion 11 extends in a horizontal direction of Y direction as a positive direction side from the top end of the perpendicular portion 10 (right side of FIG. 1). In addition, the back end portion in the Y direction is the positive direction side of the beam portion 11 is, for example, directly or indirectly electrically connected to an upper circuit board (not shown) which supplies an electrical signal for an examination.

For example, a locking portion 12 which has a larger diameter than another part and protrudes outward, is formed on an upper portion of the perpendicular portion 10 of probe 1. A taper portion 13 having its diameter gradually increasing from a lower side of the locking portion 12 towards a lower face of the locking portion 12 is formed on the face in a Y direction, which is a negative direction side (left side of FIG. 1) of the perpendicular portion 10. A lower face of the locking portion 12 is connected to an apex 13a where a diameter of the taper portion 13 is maximum. The diameter of the apex 13a of the taper portion 13 is configured equal to the inner diameter of the through-hole 2a.

The perpendicular portion 10 of probe 1 is inserted in the through-hole of probe supporting plate 2, and the locking portion 12 of perpendicular portion 10 is locked on the upper end edge on an insertion entry side of the through-hole 2a. Also, when inserting, the taper portion 13 of the probe 10 contacts the upper end portion of through-hole 2a, the perpendicular portion is guided in the Y direction, which is a positive direction side, and positioned, for example, with the perpendicular portion 10 contacted to an inner wall face in the Y direction (positive direction side) on the inside of the through-hole 2a.

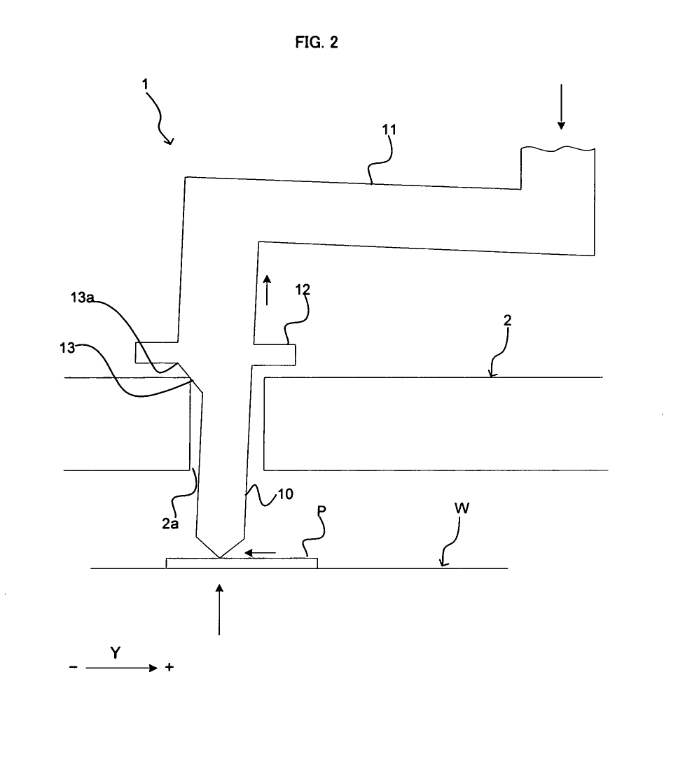

And, when the probe 1 is pressed to the electrode P of wafer W in an electrical characteristics examination as shown in FIG. 2, for example, a force in an upper direction is acting on the perpendicular portion 10 of probe 1, the beam portion 11 of probe 1 bends towards an upper side at around the rear end portion of the beam portion 11 of probe 1 acting as a fulcrum, and the perpendicular portion 10 deviates to the Y direction (negative direction) side. In this way, the perpendicular portion 10 moves to the Y direction (negative direction side) on the surface of electrode P, and the oxide film on the surface of electrode P is scraped.

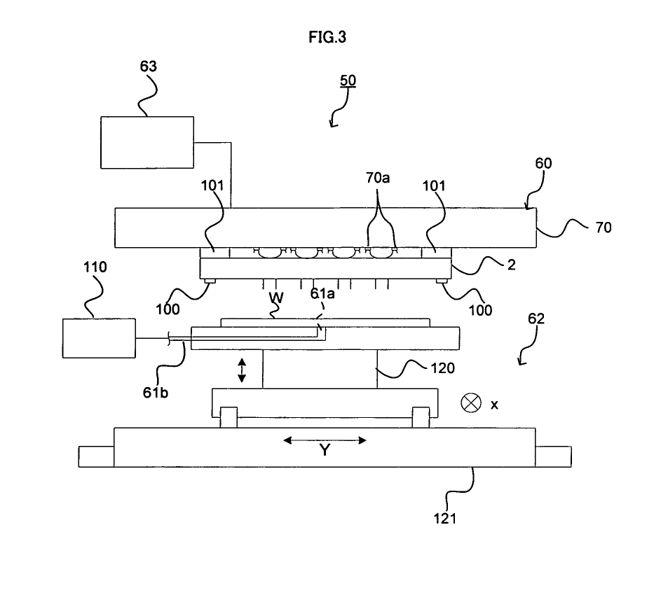

Next, an example of a prober 50 that is applied to the probe 1 configured as described above, will be discussed. FIG. 3 is an explanatory diagram showing a configuration of a prober 50.

The prober 50 is provided with, for example, a probe card 60, a chuck 61 to do vacuum holding and retain the wafer W, a moving mechanism 62 to move the chuck 61, and a tester 63.

The prove card 60 is provided with, for example, a plurality of probes 1, the probe supporting plate 2 described above to support with the probes 1 inserted, and a printed wiring board 70 as a wiring board mounted on the upper face side of the probe supporting plate 2.

The printed wiring board 70 is electrically connected to the tester 63. Inside of the printed wiring board 70, a wiring for an electrical signal for examination to travel from the tester 63 is formed, and a plurality of terminals 70a for the wiring are formed on a lower face of the print wiring board 70.

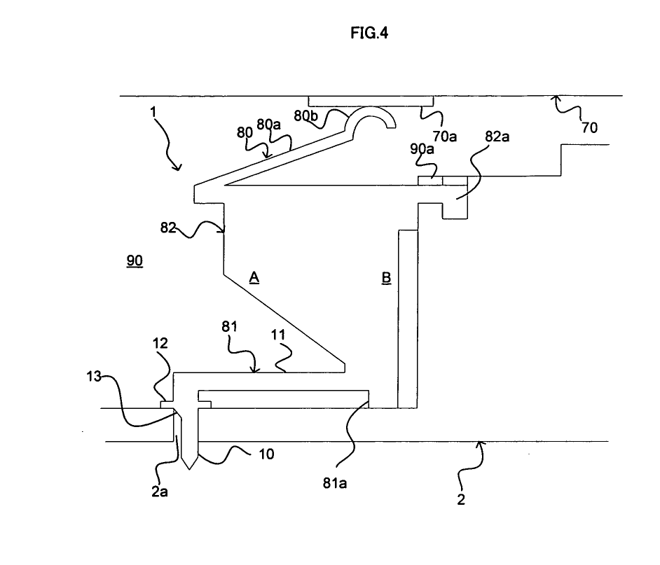

The probe 1, for example, is formed in a thin plate shape, and provided with an upper contact 80 that contacts a terminal 70a of the printed wiring board 70 as shown in FIG. 4, a lower contact 81 which is brought into a contact with electrode P of the wafer W in examination, and a main body portion 82 that connects the upper contact 80 and the lower contact 81. For example, Ni, a nickel alloy such as Ni—Co alloy or Ni—Mn alloy, W, Pd, BeCu alloy, or Au alloy are used as a material of the probe 1. The probe 1 can also be plated with precious metal plating materials, or an alloy of these precious metal plating materials, and other metal plating materials on the surface of a base material made of a material described above.

For example, the main body portion 82 of probe 1 is formed in a virtually square flat plate shape and having an inclined surface on a lower face of the one end A side (left side of FIG. 4). On the side face of the other end B side (right side of FIG. 4) of upper main body portion 82, an upper locking portion 82a that is locked to the probe supporting plate 2 is formed. The upper locking portion 82a is, for example, formed in a hook shape, protruding in a horizontal direction from the side face of main body portion 82, and having its front end bending downward.

The upper contact 80 has, for example, a linear beam portion 80a formed obliquely upward of the other end B side from an upper of the one end A side of the main body portion 82, and a curvature portion 80b which is convex and connected to the front end of beam portion 80a. The upper contact 80 has elasticity in vertical directions since the beam portion 80a bends in vertical directions. The curvature portion 80b is pressed and contacted by the terminal 70a of printed wiring board 70.

The lower contact 81 has the beam portion formed 11 in horizontal direction from the other end B side towards the one end A side of the lower portion of the main body portion 82 as described above, and the perpendicular portion 10 described above, is connected to the top end of beam portion 11. The lower contact 81 has elasticity in the vertical direction since the beam portion 11 bends in vertical directions. The locking portion 12 and the taper portion 13 described above are formed on the perpendicular portion 10. Also, for example, a stopper 81a protruding downward is formed on the lower face of the other end B side of beam portion 11.

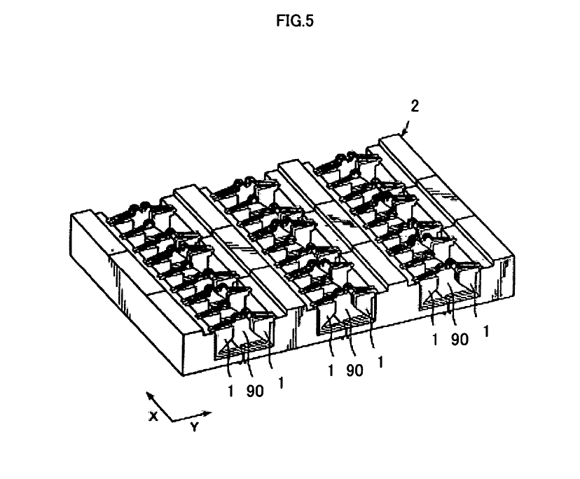

The probe supporting plate 2 is, for example, formed in a square plate shape. The probe supporting plate 2 is formed with a low-thermal expansion material, such as ceramics. On upper face side of the probe supporting plate 2, grooves 90 are formed, for example, in a plurality of rows towards a constant direction (X direction ) as shown in FIG. 5. Two rows of probe 1, for example, are locked to each row of these grooves 90 so as to face each other.

The through-hole 2a described above penetrates the lower face of the probe supporting plate 2 , as shown in FIG. 4, and is formed on a bottom face of the groove 90 of the probe supporting plate 2. Into this through-hole 2a, the perpendicular portion 10 of the lower contact 81 of probe 1 is inserted, and the lower portion of perpendicular portion 10 is protruding downward of the probe supporting plate 2. Also, the locking portion 12 of the perpendicular portion 10 locked on the upper circumference edge of through-hole 2a. On a bottom face of the groove 90, for example, a stopper 81a of the beam portion 11 is touching to maintain horizontality of the beam portion 11.

A concave portion 90a is formed on the side wall upper portion on the groove 90 of the probe supporting plate 2. The side face of concave portion 90a is opened to side wall face of the groove 90. The upper locking portion 82a on the main body portion 82 of probe 1 is locked to this concave portion 90a. In addition, the probe 1 is locked to the probe supporting plate 2 by the locking portion 12 and the upper locking portion 82a described above, and can be connected and disconnected from the upper face side of the probe supporting plate 2.

The probe supporting plate 2 supporting the plurality of probes 1 is, for example, fixed to a lower face of the printed wiring board 70 with a bolt 100 as shown in FIG. 3. For example, a support 101 is formed on the lower face of the printed wiring board 70, and an outer circumference of the probe supporting plate 2 is fixed to the support 101 with the bolt 100. In addition, the probe supporting plate 2 can be fixed to the printed wiring board 70 with other fixing members, such as a leaf spring, instead of bolt 100.

The chuck 61 is formed in a virtual disc shape having a horizontal upper face. The upper face of chuck 61 is provided with an aspiration outlet 61a to do vacuum holding the wafer W. The aspiration outlet 61a is, for example, connected to an aspiration tube 61b that leads to an external negative pressure generator 110 through the chuck 61.

The moving mechanism 62 is, for example, provided with an elevation drive portion 120, such as a cylinder to elevate the chuck 61, and an X-Y stage 121 to move the elevation drive portion 120 in two directions (X direction and Y direction) perpendicular to horizontal directions. This allows three-dimensional movement of the wafer W retained by the chuck 61, and specific probes 1 located upward can be contacted to each electrode P on the surface of wafer W.

Next, an examination process done by the prober 50 configured as above will be discussed. At first, the wafer W is done vacuum holding and retained on the chuck 61. Then, the chuck 61 is moved in the X-Y direction by the moving mechanism 62 and the position of a wafer W is adjusted. Thereafter, the chuck 61 is elevated and each electrode P on the wafer W is pressed and contacted with each probe 1 of the probe card 60.

In this case, the perpendicular portion 10 of probe 1 shown in FIG. 4 is pressed downward, and the lower contact portion 81 is bent upward at around the rear end portion of the other end (B side) of the beam portion 11 acting as a fulcrum. At this time, the perpendicular portion 10 is moved in the Y direction (negative direction) with lower end contacting the electrode P as shown in FIG. 2, and an oxide film on the surface of electrode P is scraped off (scrub). In this way, electrical continuity of the probe 1 and the electrode P on the wafer W can be made.

Thereafter, an electrical signal for examination is transmitted from the tester 63 to each probe 1 through the printed wiring board 70, and the electric signal is transmitted from each probe 1 to each electrode P on the wafer W, then electrical characteristics of the electrical circuit on the wafer W is examined.

According to the above embodiment, the taper portion 13 is formed in a Y direction (negative direction) of the perpendicular portion 10 of the probe 1, thereby positioning can be made by pulling the perpendicular portion 10 which inserted inside of the through-hole 2a of the probe supporting plate 2, aside of inner wall face of the Y direction (positive direction) side. Therefore, the positioning accuracy of the perpendicular portion 10 can be improved. Also, since a large moving space is secured on the Y direction (negative direction) side of the perpendicular portion 10, the perpendicular portion 10 can move broadly within the through-hole 2a towards Y direction (negative direction) side, and a scrub by the probe 1 on the surface of electrode P can be done properly.

Further, since the apex 13a of taper 13 is connected to the locking portion 12, the perpendicular portion 10 is guided by the taper portion 13 in the Y direction (positive direction) side when the perpendicular portion 10 is inserted into the through-hole 2a, and the perpendicular portion 10 can be locked to the locking portion 12 at the end of guide. Also, since the diameter of apex 13a of the taper portion 13 is same as the diameter of the through-hole 2a, positioning of the perpendicular portion 10 in the horizontal direction can be made with the apex 13a.

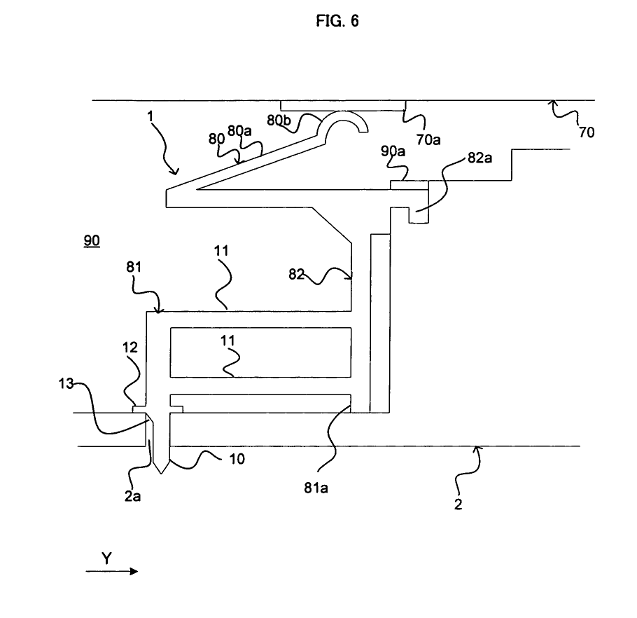

The probe 1 described in the embodiments above can be in other configurations. For example, as shown in FIG. 6, the lower contact 81 of the probe 1 having horizontal two-beam portions 11, and the perpendicular portion 10 can be formed on the top end of one end of the A side of the two-beam portions 11. In this case, the main body portion 82 can be in linear shape extending in a vertical direction connecting the rear end portion on the other end of the B side of the two-beam portions 11 and the upper contact 80.

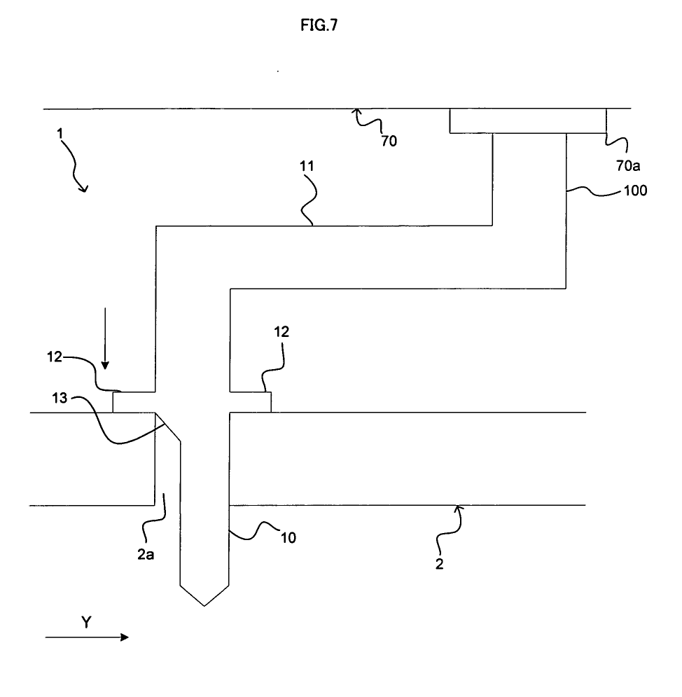

Further, the shape of probe 1 can be a so-called cantilever type that, as shown in FIG. 7, one horizontally extending beam portion 11 is connected at the upper end of perpendicular portion 10 and the perpendicular portion 100 which extends upward is connected to the beam portion 11. In this case, the upper end portion of the perpendicular portion 100 is connected to the terminal 70a of printed wiring board 70. Also, the taper portion 13 is, for example, formed on the opposite face of beam portion 11 at the perpendicular portion 10. In this example, moving space for the perpendicular portion 10 is also secured in the through-hole 2a as in the above embodiment, a scrub on the surface of electrode P with the probe 1 can be done properly.

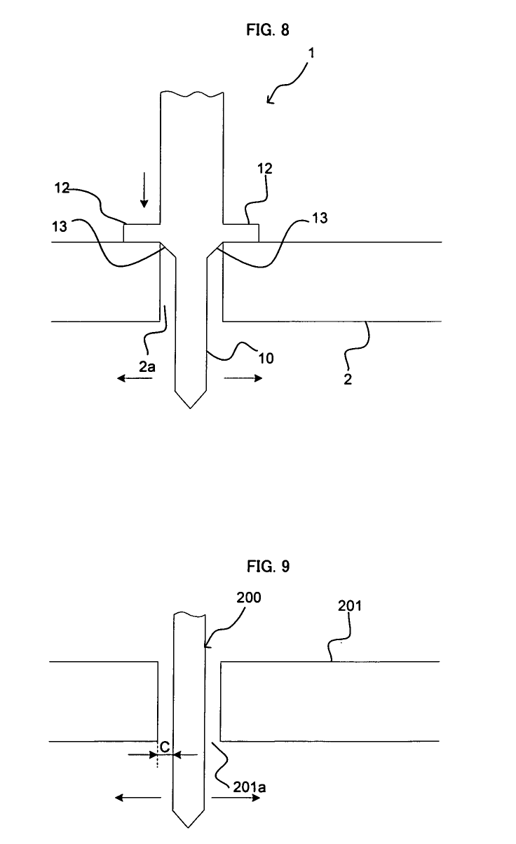

Still further, the probe 1 in the above embodiment is in a L-shape that has a horizontally extending beam portion 11 connected to the perpendicular portion 10, however, the probe 1 can be in a straight line shape that extends upward from the upper end of the perpendicular portion 10 as shown in FIG. 8. In this case, the taper 13 can be formed on both faces on the perpendicular portion 10 facing each other. In this instance, for example, when the probe 1 is inserted into the through-hole 2a, the perpendicular portion 10 is guided to the center of inside the through-hole 2a and positioned by the taper portion 13 on both faces of the perpendicular portion 10. In this way, positioning accuracy of the probe 1 is improved. Also, inside of the through-hole 2a, the perpendicular portion 10 is horizontally movable and the moving space can be secured for the perpendicular portion 10, therefore, a scrub on the surface of electrode P can be done properly with the probe 1. In addition, in this example, the taper portion 13 can be formed in circular along the entire circumference on the lateral surface of perpendicular portion 10.

The preferred embodiment of the present invention has been described in reference to the accompanying drawings; however, the present invention is not limited to such an example. It should be appreciated that one skilled in the art can think up various variations and modifications within ideas described in claims, and such variations and modifications fall within a technical scope of the present invention. For example, the probe supporting plate 2 is not limited to those of the embodiment and can be in other forms. The present invention can also be applied to a case where the examination object is a substrate such as an FPD (flat panel display) other than the wafer W.

The current invention is useful when obtaining a high probe positioning accuracy while securing moving space for the probes.

What is claimed is:

1. A probe for examining an electrical characteristic of an examination object by contacting the examination object,
wherein said probe is positioned by insertion into a through-hole of another member, having an insertion portion to be inserted into said through-hole, and a taper portion that has a diameter gradually increasing from an insertion exit side of said through-hole towards an insertion entry side.

2. The probe according to claim 1, further comprising a perpendicular portion which contacts an examination object at a lower end, and a beam portion connected to an upper end of said perpendicular portion and formed in a horizontal direction;
wherein said perpendicular potion is the insertion portion to be inserted into said through-hole; and
said taper portion is formed on said perpendicular portion.

3. The probe according to claim 2, wherein said taper portion is formed on a face on an opposite side of the direction in which said beam portion is formed relative to said perpendicular portion.

4. The probe according to claim 2, further comprising a locking portion to be locked on an edge of an insertion entry side of said through-hole is formed on said perpendicular portion.

5. The probe according to claim 4, wherein said taper portion is formed in a way that an apex where the taper diameter is a maximum, is connected to said locking portion.

6. The probe according to claim 4, wherein the diameter of the apex of said taper portion is set equal to a diameter of said through-hole.

7. A probe for examining an electrical characteristic of an examination object by contacting the examination object, wherein said probe is positioned by insertion into a through-hole of another member; and
a taper portion is formed to increase a positioning accuracy.

8. The probe according to claim 7, further comprising a perpendicular portion which contacts an examination object at a lower end, and a beam portion connected to an upper end of said perpendicular portion and formed in a horizontal direction;
wherein said perpendicular potion is an insertion portion to be inserted into said through-hole; and
said taper portion is formed on said perpendicular portion.

9. The probe according to claim 8, wherein said taper portion is formed on a face on an opposite side of a direction in which said beam portion is formed relative to said perpendicular portion.

10. The probe according to claim 8, further comprising a locking portion to be locked on an edge of an insertion entry side of said through-hole is formed on said perpendicular portion.

11. The probe according to claim 10, wherein said taper portion is formed in a way that an apex where the taper diameter is maximum, is connected to said locking portion.

12. The probe according to claim 10, wherein the diameter of the apex of said taper portion is set equal to the diameter of said through-hole.

13. A probe card comprising a probe for examining an electrical characteristic of an examination object by contacting the examination object;
wherein said probe is positioned by insertion into a through-hole of a probe supporting plate, having a insertion portion inserted into said through-hole and having a lower end contacting the examination object;
wherein said insertion portion comprising a taper portion that has a diameter gradually increasing towards an insertion entry side from an insertion exit side of said through-hole, and a locking portion locked to an edge of the inserting entry side of said through-hole; and wherein said probe supporting plate comprising a plurality of grooves in a plurality of rows and a plurality of probes are locked to said grooves through said locking portion so as to face each other.
